(19) United States
(12) Patent Application Publication
(10) Pub. No.: US 2026/0231504 A1
(43) Pub. Date: Aug. 6, 2026

(54) METHOD FOR FORMING A SOURCE/DRAIN CONTACT FOR A TRANSISTOR

(71) Applicant: TAIWAN SEMICONDUCTOR MANUFACTURING COMPANY, LTD., Hsinchu (TW)

(72) Inventors: Yi-Ju CHEN, Hsinchu (TW); Chun Ting LEE, Hsinchu (TW); Che-Chia CHANG, Hsinchu (TW); Yi-Hsin TING, Hsinchu (TW); Yi-Ren CHEN, Hsinchu (TW); Chun-Sheng LIANG, Hsinchu (TW)

(73) Assignee: TAIWAN SEMICONDUCTOR MANUFACTURING COMPANY, LTD., Hsinchu (TW)

(21) Appl. No.: 19/043,993

(22) Filed: Feb. 3, 2025

(51) Int. Cl. H10D 64/23; H10D 30/00; H10D 30/01; H10D 30/43; H10D 62/00; H10D 62/10; H10D 62/13; H10D 64/66

(52) U.S. Cl. CPC H10D 64/258; H10D 30/014; H10D 30/0191; H10D 30/43; H10D 30/502; H10D 62/021; H10D 62/121; H10D 62/151; H10D 64/668

(57) ABSTRACT

A method is provided for forming a source/drain contact for a transistor on a semiconductor substrate. The method includes a step of forming a recess in a source/drain feature of the transistor, a step of implanting dopants toward a bottom of the recess at a reference angle relative to a reference direction, and toward a sidewall of the recess at an angle that is different from the reference angle relative to the reference direction, and a step of forming a metal contact over the source/drain feature after implanting the dopants.

### BACKGROUND

The semiconductor integrated circuit (IC) industry has over the past decades experienced tremendous advancements and is still experiencing vigorous development. With the dramatic advances in IC design, new generations of ICs have smaller and more complex structures. Gate-all-around (GAA) devices (e.g., nanosheet transistors, nanorod transistors, nanowire transistors, etc.) have been developed to have a stacked channel structure surrounded by a gate structure, so as to increase the effective channel width in a transistor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a sectional view illustrating a structure of a semiconductor device in accordance with some embodiments.

FIG. 2 is a flow chart illustrating a method for forming metal contacts on the semiconductor device in accordance with some embodiments.

FIG. 3 is a top view illustrating an intermediate structure during a process of forming the metal contacts in accordance with some embodiments.

FIGS. 4 through 7 are sectional views illustrating some steps of a process of forming the metal contacts in accordance with some embodiments.

FIG. 8 is a schematic view illustrating a process step of emitting particle beams to a semiconductor substrate in accordance with some embodiments.

FIG. 9 is a top view illustrating an intermediate structure during the process of forming the metal contacts in accordance with some embodiments.

FIGS. 10 through 13 are sectional views illustrating some steps of the process of forming the metal contacts in accordance with some embodiments.

FIG. 14 is a sectional view illustrating a simulation of an intermediate structure during the process of forming the metal contacts in accordance with some embodiments.

FIG. 15 is a sectional view illustrating a structure of the semiconductor device after the process of forming the metal contacts in accordance with some embodiments.

FIG. 16 is sectional view illustrating a step of the process of forming the metal contacts in accordance with some embodiments.

FIG. 17 is a schematic view illustrating a process step of emitting particle beams to a semiconductor substrate at multiple angles in accordance with some embodiments.

FIGS. 18 through 20 are sectional views illustrating some steps of the process of forming the metal contacts in accordance with some embodiments.

FIG. 21 is a sectional view illustrating a simulation of an intermediate structure during the process of forming the metal contacts in accordance with some embodiments.

FIG. 22 is a sectional view illustrating a structure of the semiconductor device after the process of forming the metal contacts in accordance with some embodiments.

FIG. 23 is sectional view illustrating a step of the process of forming the metal contacts in accordance with some embodiments.

FIG. 24 is a sectional view illustrating a simulation of an intermediate structure during the process of forming the metal contacts in accordance with some embodiments.

FIG. 25 is a sectional view illustrating a structure of the semiconductor device after the process of forming the metal contacts in accordance with some embodiments.

FIG. 26 is a sectional view illustrating a structure of the semiconductor device after the process of forming the metal contacts in accordance with some embodiments.

FIG. 27 is a plot illustrating some profiles of concentrations of multiple elements around an interface between a silicide layer and a source/drain feature of the semiconductor device in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

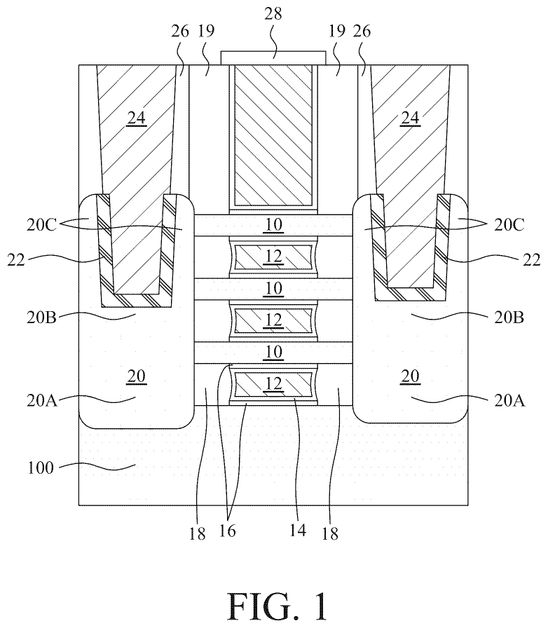

FIG. 1 illustrates a sectional view of a semiconductor device formed over a semiconductor substrate 100 in accordance with some embodiments. The semiconductor substrate 100 may be a bulk semiconductor substrate or a semiconductor-on-insulator (SOI) substrate, which may be doped (e.g., with a p-type or an n-type dopant) or undoped. In some embodiments, an SOI substrate includes a layer of a semiconductor material formed on an insulator layer. The insulator layer may be a buried oxide (BOX) layer, a silicon oxide layer or any other suitable layer. The insulator layer may be provided on a suitable substrate, such as silicon, glass or the like. The semiconductor substrate 100 may be made of a suitable semiconductor material, such as silicon or the like. In some embodiments, the semiconductor substrate 100 is a silicon wafer; and in other embodiments, the semiconductor substrate 100 is made of a compound semiconductor such as silicon carbide, gallium arsenide, indium arsenide, indium phosphide or other suitable materials. In still other embodiments, the semiconductor substrate 100 is made of an alloy semiconductor such as GaAsP, AlInAs, AlGaAs, GaInAs, GaInP, GaInAsP or other suitable materials.

In some embodiments, the semiconductor substrate 100 includes various p-type doped regions and/or n-type doped regions, such as p-type wells, n-type wells, p-type source/drain features and/or n-type source/drain features, formed by a suitable process such as ion implantation, thermal diffusion, a combination thereof, or the like. In some embodiments, the semiconductor substrate 100 may include other functional elements such as resistors, capacitors, diodes, transistors, and/or the like. The transistors are, for example, field effect transistors (FETs), such as planar FETs and/or 3D FETs (e.g., FinFETs, GAAFETs). The semiconductor substrate 100 may include lateral isolation features (e.g., shallow trench isolation (STI)) configured to separate various functional elements formed on and/or in the semiconductor substrate 100.

In the illustrative embodiment, the semiconductor device is exemplified as a gate-all-around (GAA) transistor that includes a channel feature, a gate feature, and a pair of source/drain features 20 that are connected respectively to opposite ends of the channel feature. The semiconductor device may be either a p-type GAA transistor (i.e., the source/drain features 20 are of p-type) or an n-type GAA transistor (i.e., the source/drain features 20 are of n-type). In a case where the source/drain features 20 are of p-type, the source/drain features 20 may be epitaxial features that include, for example, Si doped with boron, SiGe doped with boron, other suitable materials, or any combination thereof. In a case where the source/drain features 20 are of n-type, the source/drain features 20 may be epitaxial features that include, for example, silicon doped with phosphorus or arsenic, SiGe doped with phosphorus or arsenic, other suitable materials, or any combination thereof. In some embodiments, the semiconductor device may be of another type of transistor, such as a planar MOSFET, a FinFET, etc., and this disclosure is not limited in this respect. In the illustrative embodiment, the channel feature includes a plurality of semiconductor nanostructures (e.g., nanosheets, nanowires, etc.) that are spaced apart from each other and stacked together in a vertical direction (e.g., an up-down direction from the perspective of FIG. 1) perpendicular to a surface of the semiconductor substrate 100, and the semiconductor nanostructures serve as channel layers 10 of the GAA transistor. In accordance with some embodiments, the channel layers 10 may include, for example, p-doped silicon, n-doped silicon, other suitable materials, or any combination thereof, depending on what type of transistor the GAA transistor is. The gate feature includes a gate electrode 12 that surrounds each of the channel layers 10, and a gate dielectric 14 disposed between the gate electrode 12 and the channel layers 10. In accordance with some embodiments, the gate electrode 12 may include, for example, Cu, Ti, TiN, W, Al, Co, Ru, other suitable materials, or any combination thereof. In accordance with some embodiments, the gate electrode 12 may include various n-type or p-type work function metals. Examples of the n-type work function metal include Al, TiAlC, TiAl, or other suitable materials. Examples of p-type work function metal include TiN, WN, WCN, MoN, or other suitable materials. In accordance with some embodiments, the gate dielectric 14 may include, for example, SiN, SiCN, SiCON, SiCO, AlO, HfO, high-k materials, other suitable materials, or any combination thereof. The gate electrode 12 includes a plurality of electrode sections that are alternately stacked with the channel layers 10. Disposed between the gate dielectric 14 and the channel layers 10 are interfacial layers 16, which may include materials such as SiO₂ for enhancing adhesion between the gate dielectric 14 and the channel layers 10. The source/drain features 20 are disposed adjacent and connected to each of the channel layers 10 respectively at opposite sides of the channel feature. For each of the electrode sections of the gate electrode 12, a pair of inner spacers 18 are disposed at opposite sides of the electrode section, and each of the inner spacers 18 is disposed between the electrode section and a respective one of the source/drain features 20. In accordance with some embodiments, the inner spacers 18 may include, for example, SiO₂, SiC, SiN, SiCN, SiOC, SiON, SiCON, other suitable materials, or any combination thereof. A pair of source/drain metal contacts 24 are disposed on the source/drain features 20, respectively. In accordance with some embodiments, each of the source/drain metal contacts 24 may include a barrier layer (not shown) and an electrode body. The electrode body may include, for example, Co, W, Ru, Cu, Al, Mo, Ti, Ni, Au, Pt, Pd, other suitable conductive materials, or any combination thereof. The barrier layer is disposed to prevent metal elements in the electrode body from diffusing into surrounding dielectrics, and may include, for example, Ta, TaN, Ti, TiN, other suitable materials, or any combination thereof. In some embodiments, the barrier layer may be omitted. For each of the source/drain features 20, a silicide layer 22 is formed between the source/drain feature 20 and the respective source/drain metal contact 24, thereby improving the attachment of the source/drain metal contact 24 to the source/drain feature 20, and reducing contact resistance between the source/drain feature 20 and the source/drain metal contact 24. In accordance with some embodiments, the silicide layer 22 may include, for example, NiSi, TiSi, TiNiSi, TiSiGe, NiSiGe, TiNiSiGe, RuSi, CoSi, MoSi, PtSi, TaSi, WSi, CrSi, ZrSi, other suitable materials, or any combination thereof. A pair of top spacers 19 are disposed at opposite sides of a top section of the gate electrode 12, which is disposed at a top one of the channel layers 10. Each of the top spacers 19 is disposed between the top section of the gate electrode 12 and a respective one of the source/drain metal contacts 24. A dielectric layer 26 is disposed among the top spacers 19 and the source/drain contacts 24. The dielectric layer 26 and the top spacers 19 isolate the gate electrode 12 from the source/drain metal contacts 24. In accordance with some embodiments, the top spacers 19 may include, for example, SiO₂, SiC, SiN, SiCN, SiOC, SiON, SiCON, other suitable materials, or any combination thereof. In accordance with some embodiments, the dielectric layers 26 may include, for example, silicon nitride, other suitable materials, or any combination thereof. A protective feature 28 is disposed over the gate electrode 12, thereby protecting the gate electrode 12 from being damaged during later processes. In accordance with some embodiments, the protective feature 28 may include, for example, silicon nitride, other suitable materials, or any combination thereof.

In the illustrative embodiment, each of the source/drain metal contacts 24 extends into the respectively one of the source/drain features 20 in the vertical direction, with a bottom surface of the source/drain metal contact 24 being lower than a top surface of the second one from the top of the channel layers 10. In accordance with some embodiments, the bottom surface of the source/drain metal contact 24 is not higher than a bottom surface of the second one from the top of the channel layers 10. In other words, each of the source/drain metal contact 24 overlaps at least two of the channel layers 10 in a first horizontal direction (e.g., a direction in which the channel layers 10 extend from one source/drain feature 20 to another, which is a left-right direction from the perspective of FIG. 1) parallel to the surface of the semiconductor substrate 100, thereby increasing contact area between the source/drain metal contact 24 and the source/drain feature 20 (compared to the source/drain metal contact 24 not extending into the source/drain feature 20). Each source/drain feature 20 has a bulk portion 20A, a base contact portion 20B, and at least one arm contact portion 20C, where two arm contact portions 20C are present in the illustrative embodiment. The bulk portion 20A is disposed under a bottom of the source/drain metal contact 24. The base contact portion 20B and the arm contact portions 20C cooperatively form a U-shaped portion that is disposed over the bulk portion 20A and that extends around the bottom and two opposite sides of the source/drain metal contact 24. The base contact portion 20B is connected to the bulk portion 20A, and is disposed between the bulk portion 20A and the bottom of the source/drain metal contact 24. The arm contact portions 20C extend upward from the bulk portion 20A, are disposed at opposite sides of the source/drain metal contact 24, and thus sandwich the source/drain metal contact 24. One of the arm contact portions 20C is disposed between the source/drain metal contact 24 and the channel feature, and is connected to those of the channel layers 10 that the source/drain metal contact 24 overlaps in the first horizontal direction. The other one of the arm contact portions 20C may be, for example, disposed between the source/drain metal contact 24 and some channel layers of another semiconductor device (not shown), but this disclosure is not limited in this respect. The silicide layer 22 is disposed conformally on a top surface of the base contact portion 20B and inner surfaces of the arm contact portions 20C, extends around the bottom and two opposite sides of the source/drain metal contact 24, and thus is U-shaped. In accordance with some embodiments, a top end of the silicide layer 22 is connected to a lower end of the dielectric layer 26 as well as the source/drain metal contact 24, and extends across an interface between the dielectric layer 26 and the source/drain metal contact 24.

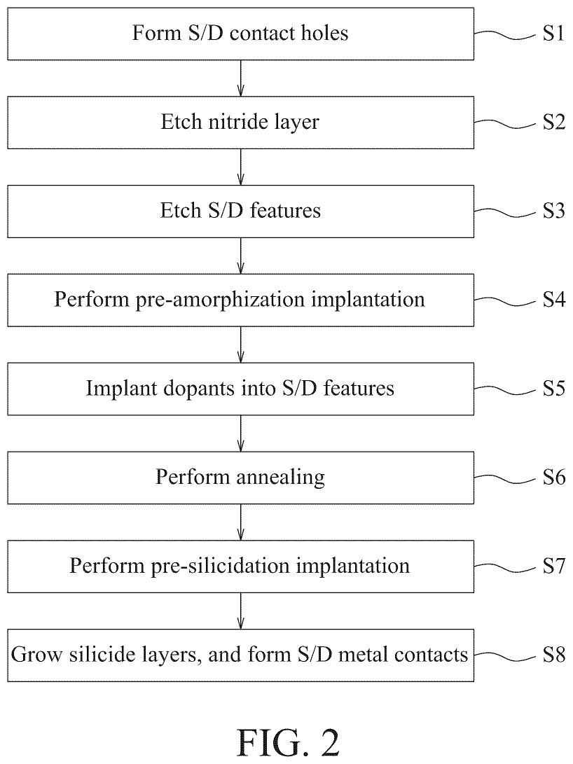

FIG. 2 is a flow chart illustrating a method for forming source/drain contacts on a transistor.

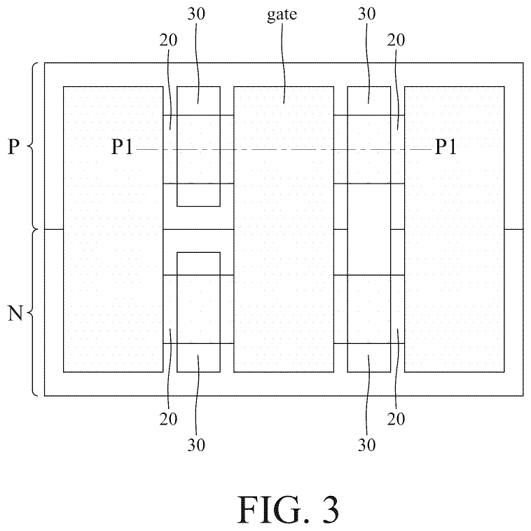

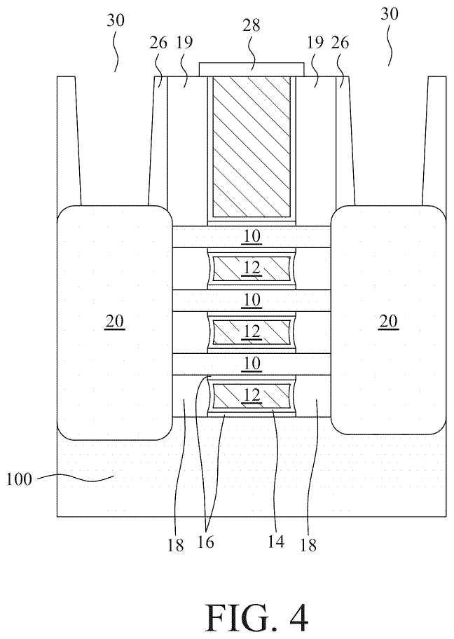

Referring to FIGS. 2 to 4, a transistor is formed over a semiconductor substrate 100, where FIG. 4 illustrates a section view taken along line P1-P1 in FIG. 3. The transistor is exemplified as a GAA transistor as described in FIG. 1, but this disclosure is not limited in this respect. In step S1, an etching process is performed to form contact holes 30 that expose the source/drain features 20, respectively. As illustrated in FIG. 3, which is a top view illustrating a structure after step S1, each of the contact holes 30 extends across corresponding source/drain feature(s) 20 in a second horizontal direction (e.g., an up-down direction from a perspective of FIG. 3) transverse to the first horizontal direction. The contact hole 30 is narrower than the corresponding source/drain feature(s) 20 in the first horizontal direction, and has a length greater than a length of each corresponding source/drain feature 20 in the second horizontal direction, thereby maximizing exposed areas of the source/drain features 20. Each of the contact holes 30 may be a local hole in a p-type region (P) where p-type transistors are formed, a local hole in an n-type region (N) where n-type transistors are formed, or extend across the p-type region (P) and the n-type region (N); however, this disclosure is not limited in this respect.

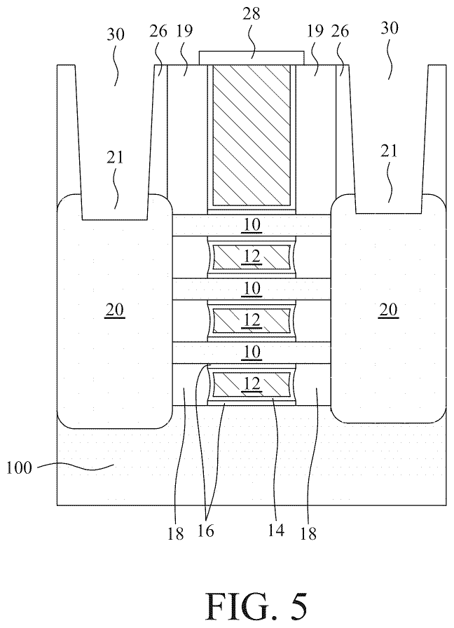

In accordance with some embodiments, after the contact holes 30 are formed to expose the source/drain features 20, a thin silicon nitride layer (not shown) may be deposited to mend the dielectric layer 26 that may be damaged in step S1, and to protect the gate feature from being damaged in subsequent process steps. In such a case, referring to FIGS. 2 and 5, an anisotropic etching may be performed to etch a portion of the thin silicon nitride layer that is disposed on the top surfaces of the source/drain features 20 (step S2), thereby exposing the source/drain features 20 from the thin silicon nitride layer. During the process of etching the thin silicon nitride layer, the source/drain features 20 may be partially etched as well, thereby creating a recess 21 in each of the source/drain features 20. In accordance with some embodiments where the thin silicon nitride layer is not formed, step S2 may be omitted.

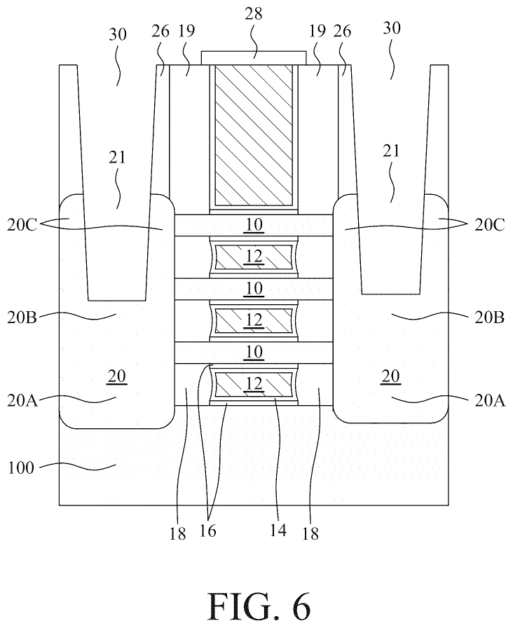

Referring to FIGS. 2 and 6, in step S3, the source/drain features 20 are etched to deepen the recesses 21 such that the recesses 21 overlap at least two of the channel layers 10 in the first horizontal direction. As a result, a bottom surface of each recess 21 is lower than the top surface of the second one from the top of the channel layers 10. In accordance with some embodiments, the bottom surface of each recess 21 is not higher than the bottom surface of the second one from the top of the channel layers 10.

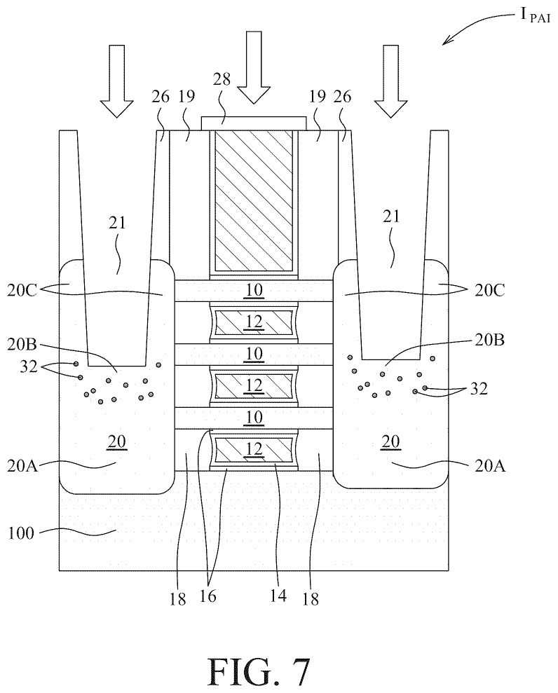

Referring to FIGS. 2 and 7, in step S4, a pre-amorphization implantation (PAI) process is performed on the source/drain features 20 by using particle beams I_{PAI} to direct implants 32 toward the bottom of the recesses 21 at a reference angle, so as to amorphize the base contact portions 20B of the source/drain features 20 where dopants are to be implanted in a subsequent process step. The amorphized region, also know as a region for solid-phase epitaxial regrowth (SPER), can enhance activation of the dopants, thereby reducing the contact resistance between the source/drain features 20 and the source/drain metal contacts 24 (see FIG. 1) that are to be formed later. In accordance with some embodiments, the implants 32 may include, for example, Ge, Si, C, other suitable elements, or any combination thereof. Since Ge has a greater atomic weight than Si and C, using Ge in the PAI process may be an option that is more time-efficient, energy-saving and cost-saving to reach a desired implant depth, which may range from about 6 nm to about 10 nm, thereby obtaining sufficient activation area of the dopants. In accordance with some embodiments, the PAI process is performed using ion beams that include charged particles (e.g., ions). In accordance with some embodiments, the PAI process is performed using atomic beams that include neutral particles (e.g., atoms), thereby preventing the implants 32 from reacting with the source/drain features 20, which may form leakage paths. In accordance with some embodiments, the reference angle is 0 degrees relative to the vertical direction, but this disclosure is not limited in this respect.

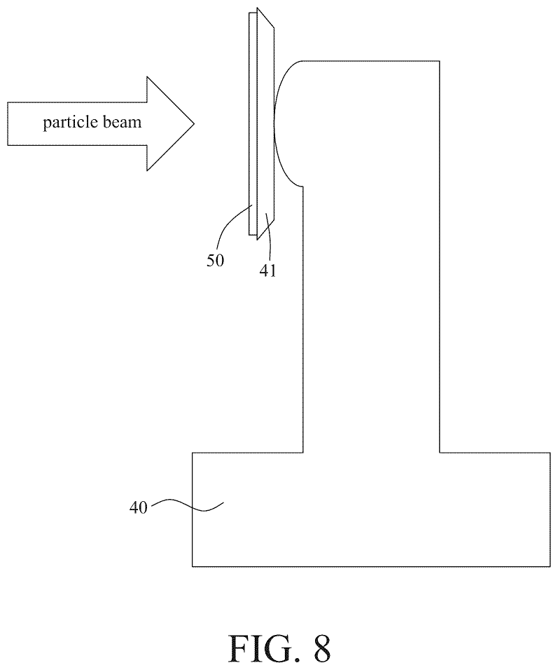

FIG. 8 exemplarily illustrates a process step of emitting particle beams toward the semiconductor substrate 100 (see FIG. 7) in accordance with some embodiments. In FIG. 8, a wafer 50 to be processed, which is analogous to the semiconductor substrate 100, is placed on a wafer stage 41 of a wafer holder 40, and a particle beam (e.g., an ion beam or an atomic beam) is emitted to the wafer 50 in a reference direction, which is a right direction from the perspective of FIG. 8. In step S4, the wafer stage 41 is set to a reference position where a backside surface of the wafer 50 faces a direction that is at the reference angle relative to the reference direction, so the implants 32 are directed toward the bottom of the recesses 21 or the base contact portions 20B of the source/drain features 20 (see FIG. 7) at the reference angle.

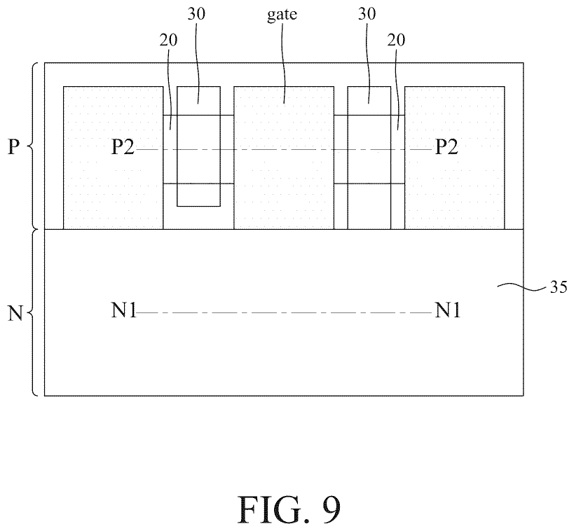

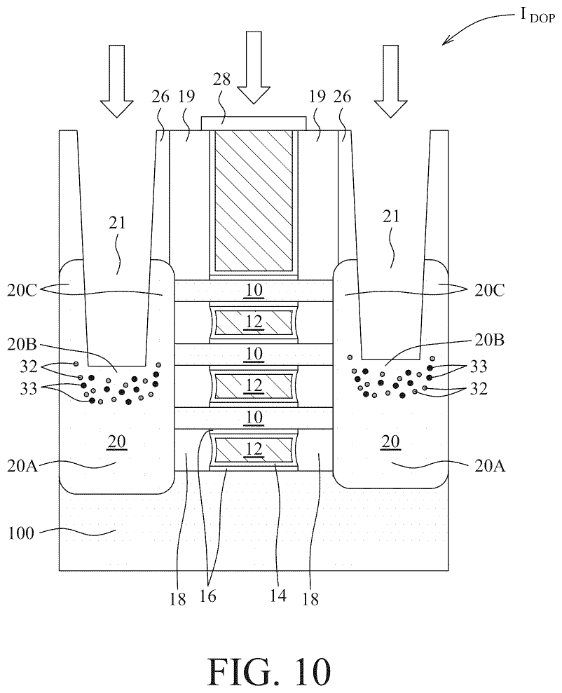

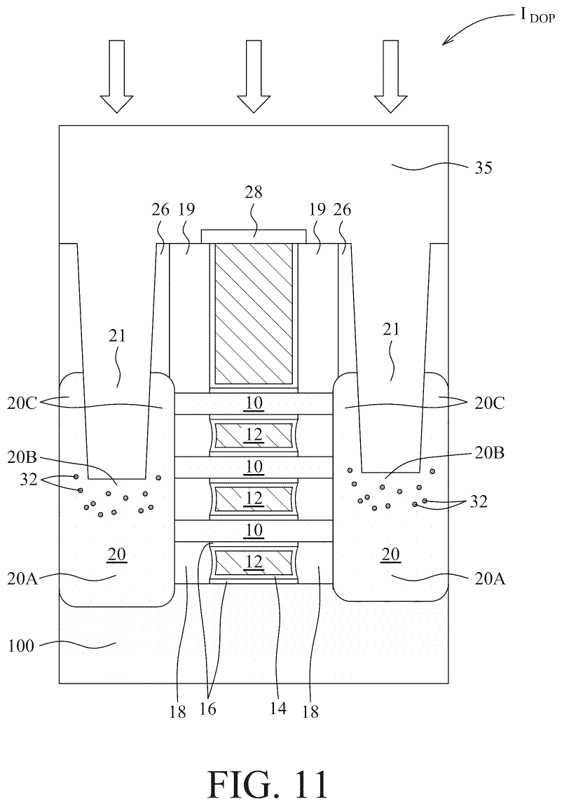

Referring to FIGS. 2, 9 and 10, in step S5, a dopant implantation process is performed on the source/drain features 20 by emitting particle beams I_{DOP} toward the bottom of the recesses 21 to implant dopants 33 into the base contact portion 20B of the source/drain features 20, where FIG. 10 is a sectional view taken along line P2-P2 in FIG. 9. In accordance with some embodiments, the particle beam I_{DOP} has a dopant concentration ranging from about 2E21 particles/cm³ to about 5E21 particles/cm³, so the source/drain features 20 have sufficient dopant concentration, thereby reducing the contact resistance of between the source/drain features 20 and the source/drain metal contacts 24 (see FIG. 1) that are to be formed later. In accordance with some embodiments, the dopants 33 are directed toward the recesses 21 at the reference angle relative to the reference direction by setting the wafer stage 41 (see FIG. 8) to the reference position, but this disclosure is not limited in this respect. In accordance with some embodiments, the dopants 33 may include, for example, boron particles, particles of other suitable trivalent elements, or any combination thereof when the source/drain features 20 are of p-type (e.g., the semiconductor device is a p-type transistor). In accordance with some embodiments, the dopants 33 may include, for example, phosphorus particles, arsenic particles, particles of other suitable pentavalent elements, or any combination thereof when the source/drain features 20 are of n-type (e.g., the semiconductor device is an n-type transistor). Referring to FIGS. 9 and 11, where FIG. 11 is a sectional view taken long line N1-N1 in FIG. 9, when the dopant implantation process is performed on the p-type region (P), the n-type region (N) may be masked using, for example, a photoresist layer 35, thereby preventing n-type source/drain features from being implanted by p-type dopants. Similarly, when the dopant implantation process is performed on the n-type region (N), the p-type region (P) may be masked, thereby preventing p-type source/drain features from being implanted by n-type dopants. In accordance with some embodiments, the dopant implantation process is not performed on the n-type region (N) when a concentration of the n-type dopants in the n-type source/drain features has been sufficiently high.

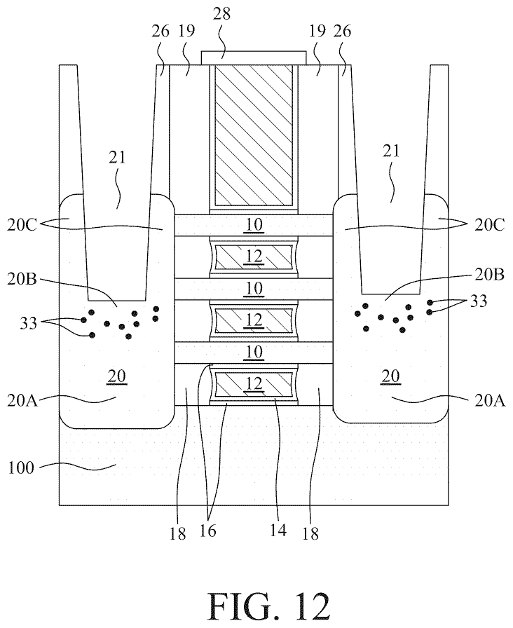

Referring to FIGS. 2 and 12, in step S6, a dynamic surface annealing (DSA) is performed on the semiconductor substrate 100, thereby activating the dopants 33 that fall within the region defined by PAI (i.e., the base contact portion 20B in this embodiment) to reduce the contact resistance between the source/drain features 20 the source/drain metal contacts 24 (see FIG. 4) that are to be formed later. During the annealing, the amorphized portions of the source/drain features 20 may be re-crystallized.

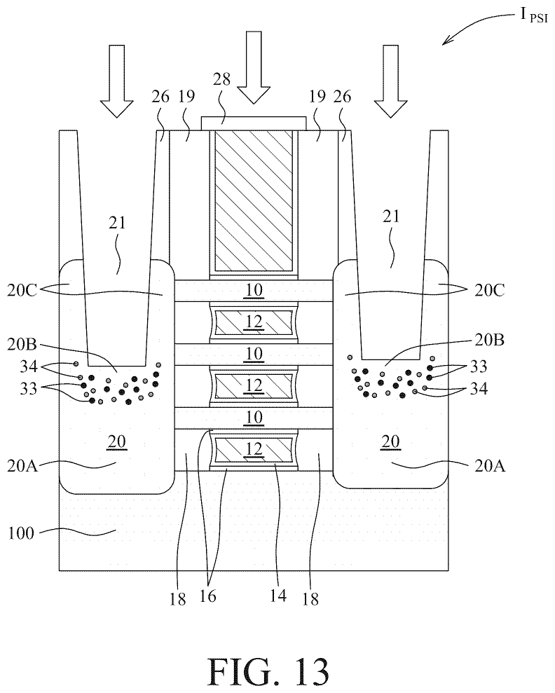

Referring to FIGS. 2 and 13, in step S7, a pre-silicidation implantation (PSI) process is performed on the source/drain features 20 by using particle beams I_{PSI} to direct implants 34 toward the bottom of the recesses 21, thereby amorphizing the base contact portions 20B of the source/drain features 20 for facilitating a subsequent silicidation process. In accordance with some embodiments, the implants 34 may include, for example, Ge, Si, C, other suitable elements, or any combination thereof. In accordance with some embodiments, a depth of the implants 34 in the source/drain features 20 to is associated with thicknesses of silicide layers to be formed on the source/drain features 20, and may range from about 3 nm to about 4 nm, but this disclosure is not limited in this respect. In accordance with some embodiments, using germanium particles as the implants 34 may allow the process to be more time-efficient, energy-saving and cost-saving due to its heavy atomic weight. In accordance with some embodiments, the PSI process is performed using ion beams that include charged particles (e.g., ions). In accordance with some embodiments, the PSI process is performed using atomic beams that include neutral particles (e.g., atoms), thereby preventing the implants 32 from reacting with the source/drain features 20, which may form leakage paths. In accordance with some embodiments, the implants 34 are directed toward the recesses 21 at the reference angle relative to the reference direction by setting the wafer stage 41 (see FIG. 8) to the reference position, but this disclosure is not limited in this respect. In accordance with some embodiments, step S7 may be omitted, and this disclosure is not limited in this respect.

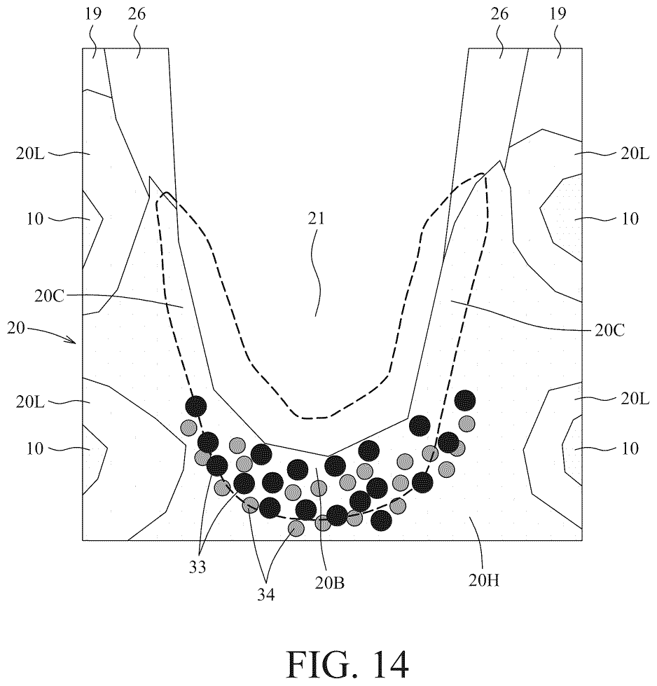

FIG. 14 illustrates a simulation of a structure around a source/drain feature 20 after step S7, where the dopants 33 and the implants 34 have been implanted in the base contact portion 20B of the source/drain feature 20 at the bottom of the recess 21, and the source/drain feature 20 includes several first epitaxial regions 20L and a second epitaxial region 20H. Atomic concentrations of germanium in the first epitaxial regions 20L are smaller than an atomic concentration of germanium in the second epitaxial region 20H, so that the first epitaxial regions 20L serve as a buffer region between the second epitaxial region 20H and the channel feature (not shown in FIG. 14), thereby preventing or alleviating current leakage between the channel feature and the source/drain feature 20. In accordance with some embodiments, the atomic concentrations of germanium in the first epitaxial regions 20L may range from about 5% to about 10%. In accordance with some embodiments, the atomic concentrations of germanium in the first epitaxial regions 20L may range from about 15% to about 25%. In accordance with some embodiments, the atomic concentration of germanium in the second epitaxial region 20H may be greater than 50%, such as in a range from about 50% to about 65%. However, this disclosure is not limited to the disclosed concentrations of germanium in different regions of the source/drain feature 20. In the subsequent silicidation process, a silicide layer is to be formed over the source/drain feature 20. The amorphized portion of the source/drain feature 20 (e.g., the base contact portion 20B in this embodiment) favors the growth of the silicide layer and tends to be transformed into silicide during the silicidation process, so the silicide layer to be formed in this embodiment may have a thicker bottom portion that is formed at the bottom of the recess 21 (e.g., on the base contact portion 20B of the source/drain feature 20), and thinner arm portions that extend upward from the bottom portion and that are formed on the sidewalls of the recess 21 (e.g., on the arm contact portions 20C of the source/drain feature 20), as exemplarily encircled using dashed lines in FIG. 14. A thicker silicide layer may cause a lower Schottky barrier between the source/drain metal contact 24 (see FIG. 1) and the source/drain feature 20, thereby reducing contact resistance. In one example of this embodiment, the bottom portion of the silicide layer may have a thickness ranging from about 5 nm to about 10 nm, and the arm portions of the silicide layer may have a thickness in a range from about 1 nm to 5 nm, but this disclosure is not limited in this respect.

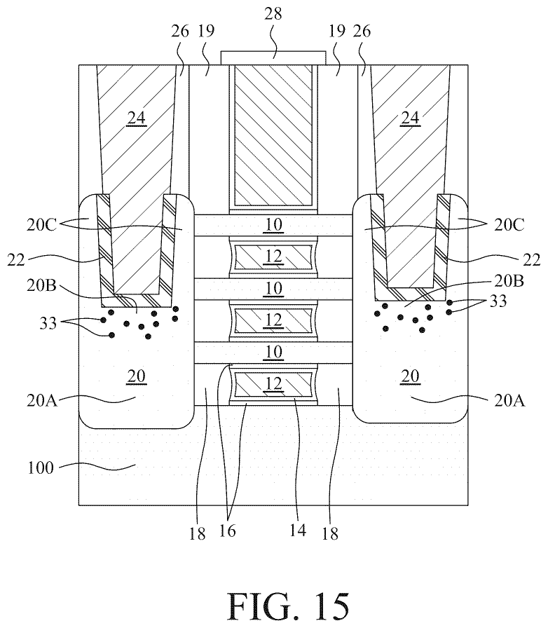

Referring to FIGS. 2 and 15, in step S8, the silicidation process is performed to grow silicide layers 22 over the source/drain features 20, and a metal layer is deposited to fill the recesses 21 (see FIG. 13), thereby forming the source/drain metal contacts 24. In accordance with some embodiments, a protective layer may be formed over the silicide layers 22 to protect the silicide layers 22 from being damaged and/or oxidized. In accordance with some embodiments, the protective layer may be formed by, for example, a chemical vapor deposition (CVD) process that uses SiH₄ and NH₃, but this disclosure is not limited in this respect. In accordance with some embodiments where the silicide layers 22 is made of TiSi, the protective layer may be made of TiSiN, but this disclosure is not limited in this respect. In accordance with some embodiments, the protective layer may be omitted.

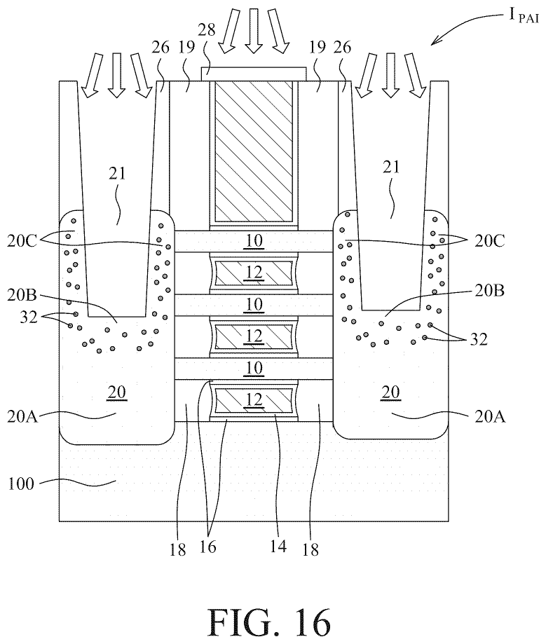

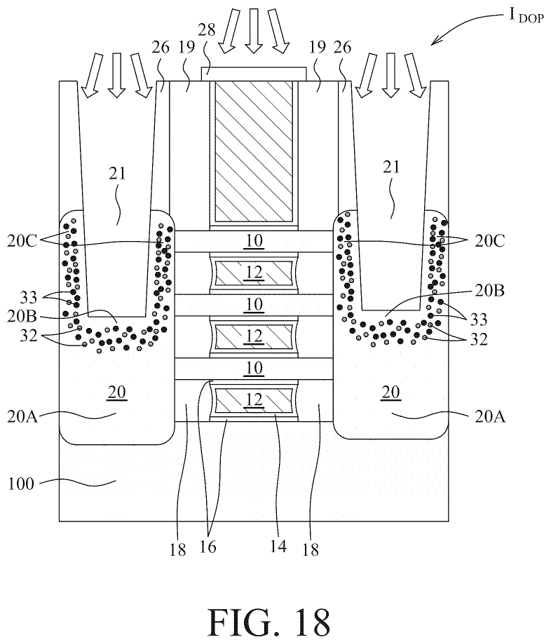

In accordance with a first variation of the embodiments of the method for forming source/drain contacts on a transistor, during the PAI process performed in step S4 (see FIG. 2), the implants 32 are further implanted toward at least one sidewall of each recess 21 at an angle that is different from the reference angle relative to the reference direction, so as to increase the region for solid-phase epitaxial regrowth. Referring to FIG. 16, in the illustrative embodiment, the implants 32 are implanted toward the recesses 21 at multiple angles relative to the reference direction. In detail, the implants 32 are implanted toward the bottom of each recess 21 (e.g., the base contact portion 20B of the source/drain feature 20) at the aforesaid reference angle, toward a first sidewall of each recess 21 (e.g., one of the arm contact portions 20C of the source/drain feature 20) at a first PAI tilt angle that is different from the reference angle, and toward an opposite second sidewall of the recess 21 (e.g., the other one of the arm contact portions 20C of the source/drain feature 20) at a second PAI tilt angle that is different from the reference angle and that is oriented differently from the first PAI tilt angle relative to the reference direction. In accordance with some embodiments, the first PAI tilt angle is greater than 0 degrees relative to the reference direction, the second PAI tilt angle is smaller than 0 degrees relative to the reference direction, and the reference angle is between the first PAI tilt angle and the second PAI tilt angle. If the tilt angle is excessively large, the implants 32 may not reach a lower portion of the target sidewall. If the tilt angle is excessively small, the implants 32 may not reach an upper portion of the target sidewall. In accordance with some embodiments, each of the first PAI tilt angle and the second PAI tilt angle is in a range from about 5 degrees to about 15 degrees, so that the implants 32 can efficiently hit the entire target sidewalls of the recesses 21. In accordance with some embodiments, the first PAI tilt angle and the second PAI tilt angle have the same magnitude, thereby achieving good symmetry in distribution of the implants 32, but this disclosure is not limited in this respect. In the first variation, using silicon and/or carbon particles as the implants 32 may ease control of implantation in depth, and reduce damages to the arm portions 20C of the source/drain features 20) due to their relatively light atomic weight, thereby preventing implants 32 and subsequently implanted dopants 33 (see FIG. 18) from entering the channel layers 10, which may result in a drain-induced barrier lowering (DIBL) issue.

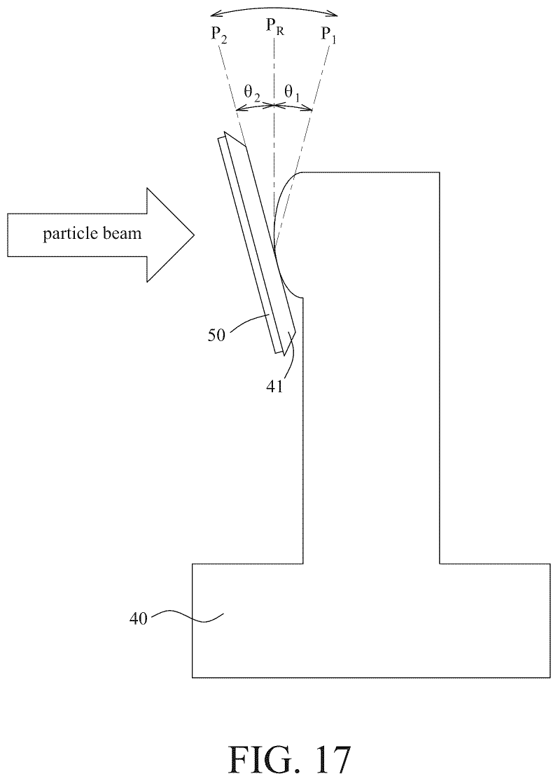

FIG. 17 exemplarily illustrates operation of emitting particle beams to a wafer 50, which is analogous to the semiconductor substrate 100 (see FIG. 16), for implantations at different angles in accordance with some embodiments. The wafer 50 is placed on the wafer stage 41 of the wafer holder 40, and the particle beam is emitted to the wafer 50 along the reference direction, which is the right direction from the perspective of FIG. 17. Referring to FIGS. 2, 16 and 17, in one operation of step S4, the wafer stage 41 is placed at the reference position P_{R} so that a backside surface of the semiconductor substrate 100 faces a direction that is at the reference angle relative to the reference direction, so the implants 32 are directed toward the recess 21 at the reference angle. In one operation of step S4, the wafer stage 41 is set to a first tilt position P₁ by tilting the wafer stage 41 from the reference position P_{R} by the first PAI tilt angle θ1 in a clockwise direction (from the perspective in FIG. 17) about a stage rotation axis that is parallel to the second horizontal direction, so the implants 32 are directed toward the first sidewalls of the recesses 21 at the first PAI tilt angle. In one operation of step S4, the wafer stage 41 is set to a second tilt position P2 by tilting the wafer stage 41 from the reference position PR by the second PAI tilt angle θ2 in a counterclockwise direction (from the perspective in FIG. 17) about the stage rotation axis, so the implants 32 are directed toward the second sidewalls of the recesses 21 at the second PAI tilt angle.

Then, referring to FIGS. 2 and 18, in step S5 of the first variation, the dopant implantation process is performed by further emitting the particle beams IDOP toward at least one sidewall of the recesses 21 that has been amorphized in step S4. In the illustrative embodiment, the dopants 33 are implanted toward the recess 21 at three different angles relative to the reference direction. In detail, the dopants 33 are implanted toward the bottom of the recess 21 at the reference angle, toward the first sidewall of the recess 21 at a first doping tilt angle that is different from the reference angle, and toward the second sidewall of the recess 21 at a second doping tilt angle that is different from the reference angle and that is oriented differently from the first doping tilt angle relative to the reference direction. In accordance with some embodiments, the first doping tilt angle is greater than 0 degrees relative to the reference direction, the second doping tilt angle is smaller than 0 degrees relative to the reference direction, and the reference angle is between the first doping tilt angle and the second doping tilt angle. In accordance with some embodiments, each of the first doping tilt angle and the second doping tilt angle is in a range from about 5 degrees to about 15 degrees, so that the dopants 33 can be efficiently and effectively implanted into the entire target side wall of the recess 21. In accordance with some embodiments, the first doping tilt angle and the second doping tilt angle have the same magnitude, thereby achieving good symmetry in distribution of the dopants 33. The first doping tilt angle may be either the same as or different from the first PAI tilt angle, and the second doping tilt angle may be either the same as or different from the second PAI tilt angle. In accordance with some embodiments, a dopant concentration of the particle beam IDOP during the implantation of the dopants 33 toward the sidewall(s) of the recess 21 is lower than a dopant concentration of the particle beam IDOP during the implantation of the dopants 33 toward the bottom of the recess 21 in order to prevent the implanted dopants 33 in the sidewall(s) of the recess 21 from entering the channel layers 10, which may result in the DIBL issue. In accordance with some embodiments, the particle beam IDOP has a dopant concentration ranging from about 2E21 particles/cm³ to about 5E21 particles/cm³ during the implantation of the dopants 33 toward the bottom of the recess 21, and has a dopant concentration in a range from about 1E20 particles/cm³ to about 1E21 particles/cm³ during the implantation of the dopants 33 toward the sidewall(s) of the recess 21. Further referring to FIG. 17, implanting the dopants 33 at multiple angles can be achieved by tilting the wafer stage 41. For example, in one operation of step S5, the wafer stage 41 is placed at the reference position, so the dopants 33 are directed toward the bottom of the recesses 21 at the reference angle; in one operation of step S5, the wafer stage 41 is tilted from the reference position by the first doping tilt angle in a first direction about the stage rotation axis, so the dopants 33 are directed toward the first sidewalls of the recesses 21 at the first doping tilt angle; and in one operation of step S5, the wafer stage 41 is tilted from the reference position by the second doping tilt angle in a second direction (opposite to the first direction) about the stage rotation axis, so the dopants 33 are directed toward the second sidewalls of the recesses 21 at the second doping tilt angle.

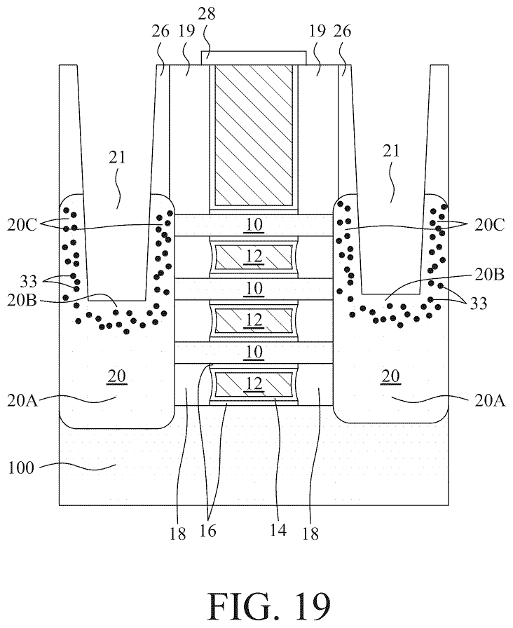

Referring to FIGS. 2 and 19, in step S6 of the first variation, the dynamic surface annealing is performed to activate the dopants 33, and the amorphized base contact portion 20B and the amorphized arm contact portions 20C of the source/drain features 20 are re-crystallized.

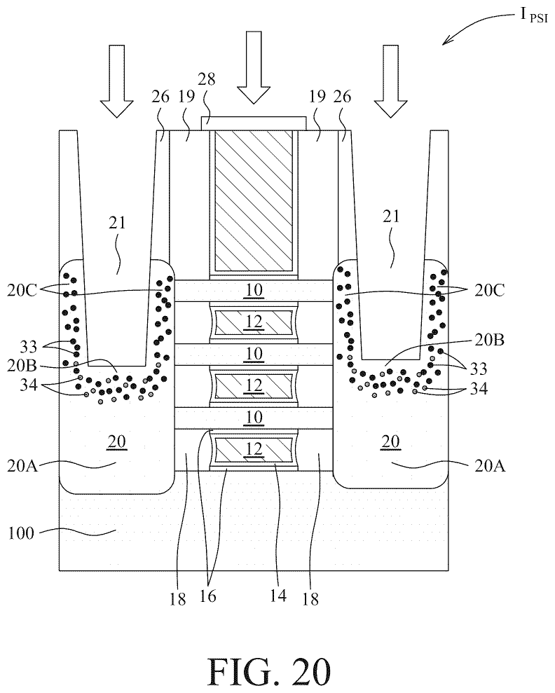

Referring to FIGS. 2 and 20, in step S7 of the first variation, the pre-silicidation implantation process is performed on the source/drain features 20 by using particle beams IPSI to direct implants 34 toward the bottom of the recesses 21, thereby amorphizing the base contact portions 20B of the source/drain features 20 for facilitating a subsequent silicidation process.

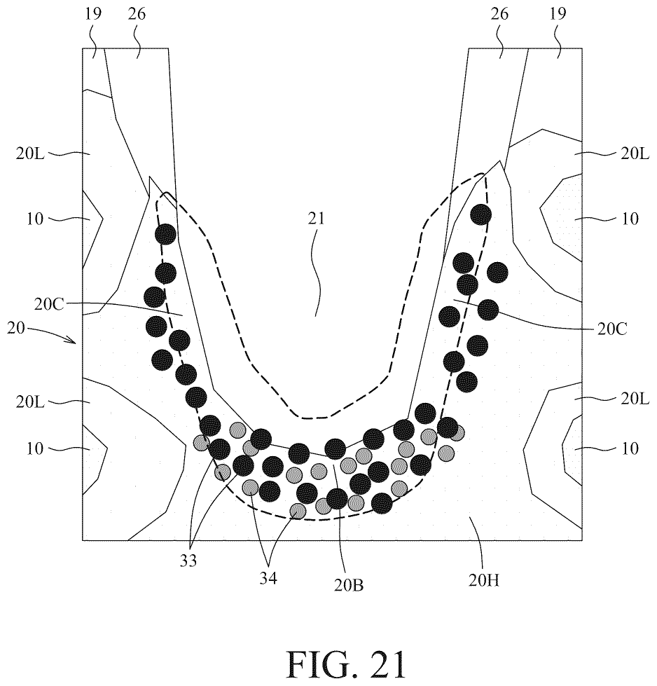

FIG. 21 illustrates a simulation of a structure around a source/drain feature 20 after step S7 of the first variation, where the dopants 33 and the implants 34 are implanted in the base contact portion 20B of the source/drain feature 20, and the dopants 33 are further implanted in the arm contact portions 20C of the source/drain feature 20. Since the base contact portion 20B has been amorphized in step S7, the silicide layer to be formed in this embodiment may have a thicker bottom portion and thinner arm portions, as exemplarily encircled using dashed lines in FIG. 21. In one example of this embodiment, the bottom portion of the silicide layer may have a thickness ranging from about 5 nm to about 10 nm, and the arm portions of the silicide layer may have a thickness in a range from about 1 nm to 5 nm, but this disclosure is not limited in this respect.

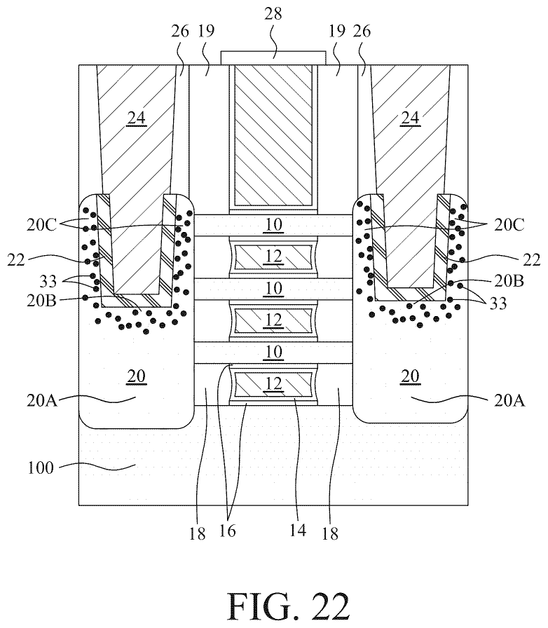

Referring to FIGS. 2 and 22, in step S8 of the first variation, the silicidation process is performed to grow silicide layers 22 over the source/drain features 20, and a metal layer is deposited to fill the recesses 21 (see FIG. 20), thereby forming the source/drain metal contacts 24.

In the first variation, the dopants 33 that are implanted into the arm contact portions 20C of the source/drain features 20 may further lower the Schottky barrier, thereby further reducing contact resistance between the source/drain metal contacts 24 and the source/drain features 20. In addition, since the dopants 33 in the arm contact portions 20C are close to the channel layers 10, channel resistance may be reduced as well.

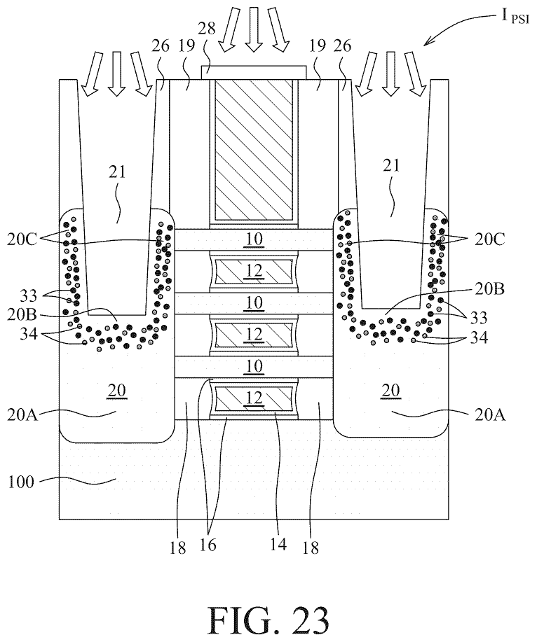

In accordance with a second variation of the embodiments of the method for forming source/drain contacts on a transistor, in addition to the operations in the first variation, the implants 34 are further implanted toward at least one sidewall of each recess 21 at an angle that is different from the reference angle relative to the reference direction during the PSI process performed in step S7 (see FIG. 2). Referring to FIG. 23, in the illustrative embodiment, the implants 34 are implanted toward the recesses 21 at multiple angles relative to the reference direction. In detail, the implants 34 are implanted toward the bottom of the recesses 21 at the reference angle, toward the first sidewalls of the recesses 21 at a first PSI tilt angle that is different from the reference angle, and toward the second sidewalls of the recesses 21 at a second PSI tilt angle that is different from the reference angle and that is oriented differently from the first PSI tilt angle relative to the reference direction. In accordance with some embodiments, the first PSI tilt angle is greater than 0 degrees relative to the reference direction, the second PSI tilt angle is smaller than 0 degrees relative to the reference direction, and the reference angle is between the first PSI tilt angle and the second PSI tilt angle. In accordance with some embodiments, each of the first PSI tilt angle and the second PSI tilt angle is in a range from about 5 degrees to about 15 degrees, so that the implants 34 can efficiently and effectively hit the entire target sidewalls of the recesses 21. In accordance with some embodiments, the first PSI tilt angle and the second PSI tilt angle have the same magnitude, thereby achieving good symmetry in distribution of the implants 32, but this disclosure is not limited in this respect. The first PSI tilt angle may be either the same as one of the first PAI tilt angle and the first doping tilt angle, or different from each of the first PAI tilt angle and the first doping tilt angle. The second PSI tilt angle may be either the same as one of the second PAI tilt angle and the second doping tilt angle, or different from each of the second PAI tilt angle and the second doping tilt angle. Further referring to FIG. 17, implanting the implants 34 at multiple angles can be achieved by tilting the wafer stage 41. For example, in one operation of step S7, the wafer stage 41 is placed at the reference position, so the implants 34 are directed toward the bottom of the recesses 21 at the reference angle; in one operation of step S7, the wafer stage 41 is tilted from the reference position by the first PSI tilt angle in the first direction about the stage rotation axis, so the implants 34 are directed toward the first sidewalls of the recesses 21 at the first PSI tilt angle; and in one operation of step S7, the wafer stage 41 is tilted from the reference position by the second PSI tilt angle in a second direction (opposite to the first direction) about the stage rotation axis, so the implants 34 are directed toward the second sidewalls of the recesses 21 at the second doping tilt angle. In accordance with some embodiments, the depths of the implants 34 in the base contact portions 20B and the arm contact portions 20C of the source/drain features may range from about 3 nm to about 4 nm, which is associated with a desired thickness of the silicide layer that is to be formed later, but this disclosure is not limited in this respect.

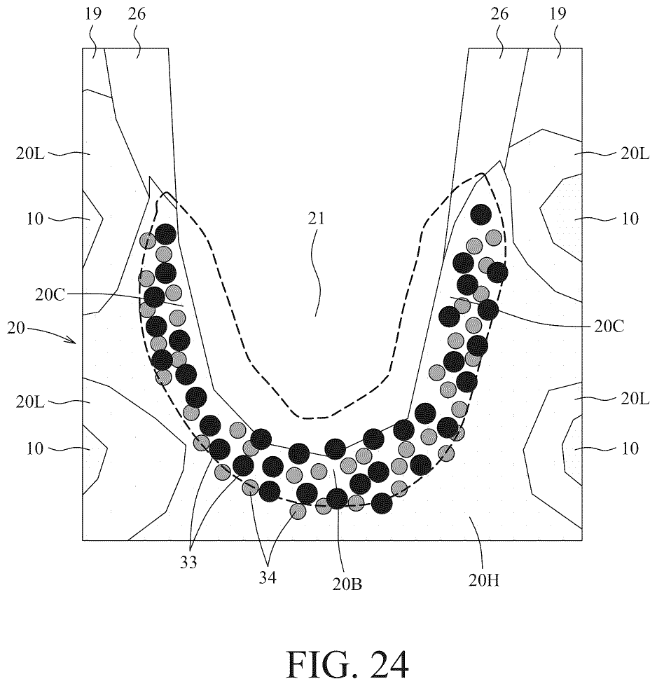

FIG. 24 illustrates a simulation of a structure around a source/drain feature 20 after step S7 of the second variation, where both of the dopants 33 and the implants 34 are implanted in not only the base contact portion 20B but also the arm contact portions 20C of the source/drain feature 20. Since the base contact portion 20B and the arm contact portions 20C of the source/drain feature 20 have been amorphized in step S7, the silicide layer to be formed in this embodiment may have not only a thick bottom portion but also thick arm portions, as exemplarily encircled using dashed lines in FIG. 24. In one example of this embodiment, each of the bottom portion and the arm portions of the silicide layer may have a thickness ranging from about 5 nm to about 10 nm, thereby further lowering the Schottky barrier between the source/drain metal contacts 24 and the source/drain features 20. An excessively thin silicide layer may not effectively reduce contact resistance between the source/drain metal contacts 24 and the source/drain features 20, while an excessively thick silicide layer may not provide additional benefits could prolong the processing time.

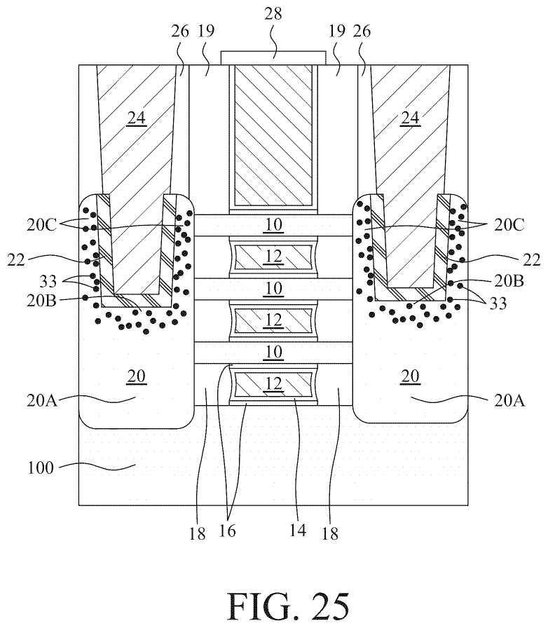

Referring to FIGS. 2 and 25, in step S8 of the second variation, the silicidation process is performed to grow silicide layers 22 over the source/drain features 20, and a metal layer is deposited to fill the recesses 21 (see FIG. 23), thereby forming the source/drain metal contacts 24. In the resultant structure of the second variation, an atomic concentration of germanium in the base contact portion 20B of the source/drain feature 20 may range from about 50% to about 55%; an atomic concentration of germanium in the arm contact portions 20C of the source/drain feature 20 may range from about 25% to about 40%; a concentration of the dopants 33 in the base contact portion 20B of the source/drain feature 20 may range from about 1.5E21 particles/cm⁻³ to about 5E21 particles/cm⁻³; and a concentration of the dopants 33 in the base portion 20B of the source/drain feature 20 may range from about 5E20 particles/cm⁻³ to about 2E21 particles/cm⁻³.

In accordance with some embodiments, a process of depositing a molybdenum layer to form the source/drain metal contacts may involve use of MoCl₅, which may etch the silicide layers 22, and the loss of the silicide layers 22 may cause damage to the source/drain features 20 and poor contact between the source/drain metal contacts 24 and the source/drain features 20. The second variation enables the silicide layers 20 to have not only a thick bottom portion but also thick arm portions, thereby favoring formation of molybdenum as the source/drain metal contacts 24, which may lower the resistance of the source/drain metal contact 24 in comparison with tungsten, which is commonly used as a major material in the source/drain metal contacts 24. In accordance with some embodiments, each silicide layer 22 is configured to have a thickness ranging from about 5 nm to about 10 nm at each of its bottom portion and arm portions after the process of depositing the molybdenum layer, thereby achieving a good contact resistance between the source/drain metal contacts 24 and the source/drain features 20.

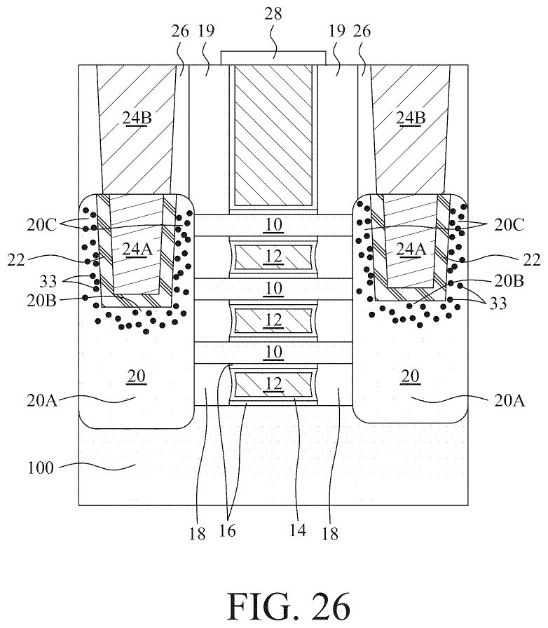

Referring to FIG. 26, since the second variation facilitates formation of molybdenum, in some embodiments, the source/drain metal contacts 24 may be formed to include a cap portion 24A that is disposed over the silicide layers 22 and fills the recesses 21 (see FIG. 23), and a body portion 24B that is disposed over the cap portion 24A and made of a different metal material, such as tungsten, which can be deposited using a relatively mature process to reduce processing time and save cost.

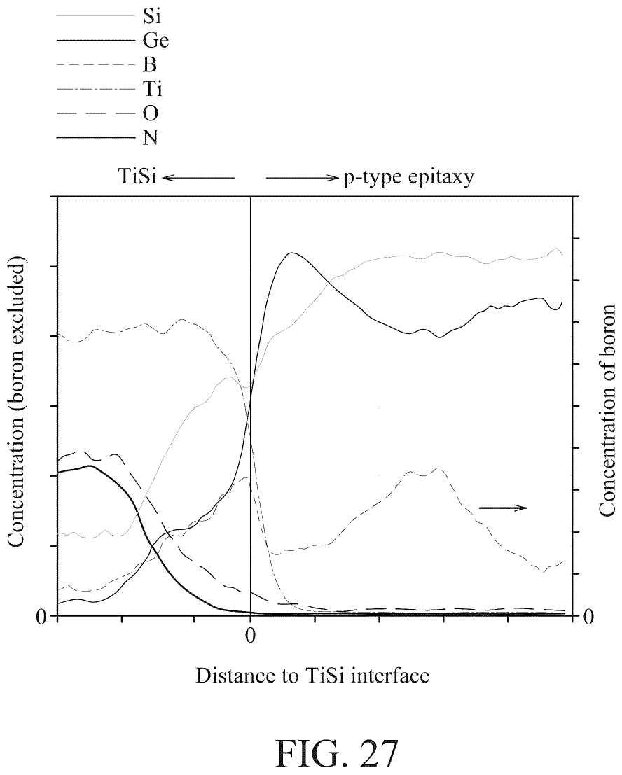

FIG. 27 is a plot illustrating some profiles of concentrations of different elements around an interface between the silicide layer 22 and the source/drain feature 20 in an example of the second variation. In this example, the silicide layer 22 is made of TiSi, and the source/drain feature 20 is made of SiGe doped with boron. It can be seen that the concentration of boron, which is used as the dopants 33 in this example, gradually increases in a surface portion of the source/drain features 20 from the interface toward the interior of the source/drain features 20, reaching a peak value before gradually decreasing. The peak value of the boron concentration results from the dopant implantation in step S5 (see FIG. 2), so the earliest embodiment may have such a profile of boron concentration only in the base contact portions 20B of the source/drain features 20 (see FIG. 15), while the first and second variations may have such a profile of boron concentration in not only the base contact portion 20B but also the arm contact portions 20C of the source/drain features 20 (see FIGS. 22, 25 and 26), thereby achieving a better contact resistance between the source/drain metal contacts 24 and the source/drain feature 20 as well as a better channel resistance. In accordance with some embodiments, the peak value of the boron concentration in the surface portion of the source/drain features 20 (or, in the base contact portions 20B and the arm contact portions 20C of the source/drain features 20) is greater than 3 times a boron concentration in the bulk portions 20A of the source/drain features 20. In accordance with some embodiments, an average boron concentration in a surface portion of the source/drain feature 20 (e.g., the base contact portion 20B and the arm contact portions 20C) is greater than an average boron concentration in the bulk portion 20A of the source/drain feature 20. In accordance with some embodiments, the peak value of the boron concentration lies in a depth that is in a range from about 3 nm to about 7 nm away from the interface between the silicide layer 22 and the source/drain feature 20, but this disclosure is not limited in this respect.

In accordance with some embodiments, a method is provided for forming a source/drain contact for a transistor on a semiconductor substrate. In one step, a recess is formed in a source/drain feature of the transistor. In one step, dopants are implanted toward a bottom of the recess at a reference angle relative to a reference direction, and toward a sidewall of the recess at a first doping tilt angle that is different from the reference angle relative to the reference direction. In one step, a metal contact is formed over the source/drain feature after implanting the dopants.

In accordance with some embodiments, in one step before the implanting of the dopants and after the forming of the recess, pre-amorphization implantation (PAI) is performed on the source/drain feature by directing first implants toward the bottom of the recess at the reference angle, and toward the sidewall of the recess at a first PAI tilt angle that is different from the reference angle relative to the reference direction.

In accordance with some embodiments, the method includes some steps after the implanting of the dopants. In one of those steps, an annealing process is performed on the semiconductor substrate. In one of those steps after the annealing process, pre-silicidation implantation (PSI) is performed on the source/drain feature by directing second implants toward the bottom of the recess at the reference angle, and toward the sidewall of the recess at a first PSI tilt angle that is different from the reference angle relative to the reference direction. In one of those steps, a conformal silicide layer is formed in the recess of the source/drain feature after the pre-silicidation implantation. The metal contact is formed over the conformal silicide layer.

In accordance with some embodiments, the first implants include particles selected from a group consisting of germanium, silicon and carbon.

In accordance with some embodiments, the method includes some steps after the implanting of the dopants. In one of those steps, pre-silicidation implantation (PSI) is performed on the source/drain feature by directing implants toward the bottom of the recess at the reference angle, and toward the sidewall of the recess at a first PSI tilt angle that is different from the reference angle relative to the reference direction. In one of those steps, a conformal silicide layer is formed over the source/drain feature after the pre-silicidation implantation. The metal contact is formed over the conformal silicide layer.

In accordance with some embodiments, the conformal silicide layer is formed to have a first portion disposed on the bottom of the recess and having a thickness greater than 5 nm, and a second portion disposed on the sidewall of the recess and having a thickness greater than 5 nm.

In accordance with some embodiments, the metal contact has a first portion formed in the recess and including molybdenum.

In accordance with some embodiments, the metal contact has a second portion formed over the first portion and including a metal element that is different from molybdenum.

In accordance with some embodiments, the implanting of the dopants further includes implanting the dopants toward an opposite sidewall of the recess at a second doping tilt angle that is different from the reference angle relative to the reference direction, and that is oriented differently from the first doping tilt angle relative to the reference direction.

In accordance with some embodiments, the implanting of the dopants at the reference angle is performed by placing the semiconductor substrate on a wafer stage set to a reference position so that a surface of the semiconductor faces a direction at the reference angle relative to the reference direction, and by implanting the dopants toward the semiconductor substrate in the reference direction. The implanting of the dopants at the first doping tilt angle is performed by tilting the wafer stage from the reference position by the first doping tilt angle in a first tilting direction, and implanting the dopants toward the semiconductor substrate in the reference direction. The implanting of the dopants at the second doping tilt angle is performed by tilting the wafer stage from the reference position by the second doping tilt angle in a second tilting direction opposite to the first tilting direction, and implanting the dopants toward the semiconductor substrate in the reference direction.

In accordance with some embodiments, the transistor includes a plurality of channel layers connected to the source/drain feature, the plurality of channel layers being spaced apart from each other and stacked together. The recess overlaps at least two of the plurality of channel layers in a direction parallel to a surface of the semiconductor substrate.

In accordance with some embodiments, the first doping tilt angle is in a range from 5 degrees to 15 degrees.

In accordance with some embodiments, a particle beam used to implant the dopants at the reference angle has a first dopant concentration, and a particle beam used to implant the dopants at the first doping tilt angle has a second dopant concentration smaller from the first dopant concentration.

In accordance with some embodiments, an average dopant concentration in a surface portion of the source/drain feature is greater than an average dopant concentration in a bulk portion of the source/drain feature.

In accordance with some embodiments, a method is provided for forming a source/drain contact for a transistor on a semiconductor substrate. The transistor includes a plurality of channel layers spaced apart from each other and stacked together. In one step, a source/drain feature of the transistor that is connected to the plurality of channel layers is etched, thereby forming a recess in the source/drain feature, where the recess has a bottom surface that is lower than a top surface of a second one from a top of the plurality of channel layers. In one step, pre-amorphization implant (PAI) particle beams are emitted to the source/drain feature at a reference angle toward a bottom surface of the recess, at a first PAI tilt angle toward a first sidewall of the recess, and at a second PAI tilt angle toward a second sidewall of the recess that is opposite to the first sidewall. In one step after the emitting of the PAI particle beams, dopants are implanted to the source/drain feature at the reference angle toward the bottom surface of the recess, at a first doping tilt angle toward the first sidewall of the recess, and at a second doping tilt angle toward the second sidewall of the recess. In one embodiment after the implanting of the dopants, a metal contact is formed over the source/drain feature.

In accordance with some embodiments, the method includes some steps before the forming of the metal contact and after the implanting of the dopants. In one of those steps, pre-silicidation implant (PSI) particle beams are emitted to the source/drain feature at the reference angle toward the bottom surface of the recess, at a first PSI tilt angle toward the first sidewall of the recess, and at a second PSI tilt angle toward the second sidewall of the recess. In one of those steps after the emitting of the PSI particle beams, a conformal silicide layer is formed over the source/drain features and in the recess. The metal contact is formed over the conformal silicide layer.

In accordance with some embodiments, the metal contact includes molybdenum.

In accordance with some embodiments, the metal contact includes a cap portion and a body portion, and the forming of the metal contact includes forming the cap portion that includes molybdenum and that fills the recess, and forming the body portion that includes a metal element that is different from molybdenum over the cap portion.

In accordance with some embodiments, a semiconductor device is provided to include a plurality of channel layers, a gate feature, a first source/drain feature, a second source/drain feature, a first metal contact, and a second metal contact. The channel layers are disposed on a semiconductor substrate, are spaced apart from each other, and are stacked together. The gate feature surrounds the plurality of channel layers. The first source/drain feature is connected to the plurality of channel layers. The second source/drain feature is spaced apart from the first source/drain feature and is connected to the plurality of channel layers. The first metal contact extends into the first source/drain feature, and overlaps at least two of the plurality of channel layers in a direction parallel to a surface of the semiconductor substrate. The second metal contact is disposed over the second source/drain feature. The first source/drain feature has a bulk portion, and an arm portion extending from the bulk portion and disposed between the first metal contact and the at least two of the plurality of channel layers, and the arm portion has a dopant concentration greater than a dopant concentration in the bulk portion.

In accordance with some embodiments, the semiconductor device further includes a silicide layer disposed between the first metal contact and the bulk portion of the first source/drain feature, and between the first metal contact and the arm portion of the first source/drain feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a source/drain contact for a transistor on a semiconductor substrate, comprising:
forming a recess in a source/drain feature of the transistor;
implanting dopants toward a bottom of the recess at a reference angle relative to a reference direction, and toward a sidewall of the recess at a first doping tilt angle that is different from the reference angle relative to the reference direction; and
forming a metal contact over the source/drain feature after implanting the dopants.

2. The method according to claim 1, further comprising, before the implanting of the dopants and after the forming of the recess, performing pre-amorphization implantation (PAI) on the source/drain feature by directing first implants toward the bottom of the recess at the reference angle, and toward the sidewall of the recess at a first PAI tilt angle that is different from the reference angle relative to the reference direction.

3. The method according to claim 2, further comprising, after the implanting of the dopants:
performing an annealing process on the semiconductor substrate;
performing, after the annealing process, pre-silicidation implantation (PSI) on the source/drain feature by directing second implants toward the bottom of the recess at the reference angle, and toward the sidewall of the recess at a first PSI tilt angle that is different from the reference angle relative to the reference direction; and
forming a conformal silicide layer in the recess of the source/drain feature after the pre-silicidation implantation,
wherein the metal contact is formed over the conformal silicide layer.

4. The method according to claim 2, wherein the first implants include particles selected from a group consisting of germanium, silicon and carbon.

5. The method according to claim 1, further comprising, after the implanting of the dopants:
performing pre-silicidation implantation (PSI) on the source/drain feature by directing implants toward the bottom of the recess at the reference angle, and toward the sidewall of the recess at a first PSI tilt angle that is different from the reference angle relative to the reference direction; and
forming a conformal silicide layer over the source/drain feature after the pre-silicidation implantation,
wherein the metal contact is formed over the conformal silicide layer.

6. The method according to claim 5, wherein the conformal silicide layer is formed to have a first portion disposed on the bottom of the recess and having a thickness greater than 5 nm, and a second portion disposed on the sidewall of the recess and having a thickness greater than 5 nm.

7. The method according to claim 6, wherein the metal contact has a first portion formed in the recess and including molybdenum.

8. The method according to claim 7, wherein the metal contact has a second portion formed over the first portion and including a metal element that is different from molybdenum.

9. The method according to claim 1, wherein the implanting of the dopants further includes implanting the dopants toward an opposite sidewall of the recess at a second doping tilt angle that is different from the reference angle relative to the reference direction, and that is oriented differently from the first doping tilt angle relative to the reference direction.

10. The method according to claim 9, wherein the implanting of the dopants at the reference angle is performed by placing the semiconductor substrate on a wafer stage set to a reference position so that a surface of the semiconductor faces a direction at the reference angle relative to the reference direction, and by implanting the dopants toward the semiconductor substrate in the reference direction;
wherein the implanting of the dopants at the first doping tilt angle is performed by tilting the wafer stage from the reference position by the first doping tilt angle in a first tilting direction, and implanting the dopants toward the semiconductor substrate in the reference direction; and
wherein the implanting of the dopants at the second doping tilt angle is performed by tilting the wafer stage from the reference position by the second doping tilt angle in a second tilting direction opposite to the first tilting direction, and implanting the dopants toward the semiconductor substrate in the reference direction.

11. The method according to claim 1, wherein the transistor includes a plurality of channel layers connected to the source/drain feature, the plurality of channel layers being spaced apart from each other and stacked together; and
wherein the recess overlaps at least two of the plurality of channel layers in a direction parallel to a surface of the semiconductor substrate.

12. The method according to claim 1, wherein the first doping tilt angle is in a range from 5 degrees to 15 degrees.

13. The method according to claim 1, wherein a particle beam used to implant the dopants at the reference angle has a first dopant concentration, and a particle beam used to implant the dopants at the first doping tilt angle has a second dopant concentration smaller from the first dopant concentration.

14. The method according to claim 1, wherein an average dopant concentration in a surface portion of the source/drain feature is greater than an average dopant concentration in a bulk portion of the source/drain feature.

15. A method for forming a source/drain contact for a transistor on a semiconductor substrate, the transistor including a plurality of channel layers spaced apart from each other and stacked together, said method comprising:
etching a source/drain feature of the transistor that is connected to the plurality of channel layers, thereby forming a recess in the source/drain feature, where the recess has a bottom surface that is lower than a top surface of a second one from a top of the plurality of channel layers;
emitting pre-amorphization implant (PAI) particle beams to the source/drain feature at a reference angle toward a bottom surface of the recess, at a first PAI tilt angle toward a first sidewall of the recess, and at a second PAI tilt angle toward a second sidewall of the recess that is opposite to the first sidewall;
after the emitting of the PAI particle beams, implanting dopants to the source/drain feature at the reference angle toward the bottom surface of the recess, at a first doping tilt angle toward the first sidewall of the recess, and at a second doping tilt angle toward the second sidewall of the recess; and
after the implanting of the dopants, forming a metal contact over the source/drain feature.

16. The method according to claim 15, further comprising, before the forming of the metal contact and after the implanting of the dopants:
emitting pre-silicidation implant (PSI) particle beams to the source/drain feature at the reference angle toward the bottom surface of the recess, at a first PSI tilt angle toward the first sidewall of the recess, and at a second PSI tilt angle toward the second sidewall of the recess; and
after the emitting of the PSI particle beams, forming a conformal silicide layer over the source/drain features and in the recess,
wherein the metal contact is formed over the conformal silicide layer.

17. The method according to claim 16, wherein the metal contact includes molybdenum.

18. The method according to claim 16, wherein the metal contact includes a cap portion and a body portion, and the forming of the metal contact includes:
forming the cap portion that includes molybdenum and that fills the recess; and
forming the body portion that includes a metal element that is different from molybdenum over the cap portion.

19. A semiconductor device, comprising:
a plurality of channel layers disposed on a semiconductor substrate, spaced apart from each other, and stacked together;
a gate feature surrounding the plurality of channel layers;
a first source/drain feature connected to the plurality of channel layers;
a second source/drain feature spaced apart from the first source/drain feature and connected to the plurality of channel layers;
a first metal contact extending into the first source/drain feature, and overlapping at least two of the plurality of channel layers in a direction parallel to a surface of the semiconductor substrate; and
a second metal contact disposed over the second source/drain feature;
wherein the first source/drain feature has a bulk portion, and an arm portion extending from the bulk portion and disposed between the first metal contact and the at least two of the plurality of channel layers, and the arm portion has a dopant concentration greater than a dopant concentration in the bulk portion.

20. The semiconductor device according to claim 19, further comprising a silicide layer disposed between the first metal contact and the bulk portion of the first source/drain feature, and between the first metal contact and the arm portion of the first source/drain feature.
